(19) United States
(12) Patent Application Publication
(10) Pub. No.: US 2007/0243701 A1
(43) Pub. Date: Oct. 18, 2007

(54) Semiconductor device fabrication method using ultra-rapid thermal annealing

(76) Inventors: Takayuki Ito, Kawasaki-shi (JP); Kyoichi Suguro, Yokohama-shi (JP); Takaharu Itani, Yokohama-shi (JP); Yoshihiko Saito, Yokosuka-shi (JP)

Correspondence Address: FINNEGAN, HENDERSON, FARABOW, GARRETT & DUNNER;LLP, 901 NEW YORK AVENUE, NW, WASHINGTON, DC, 20001-4413, US

(21) Appl. No.: 11/783,035

(22) Filed: Apr. 5, 2007

(30) Foreign Application Priority Data
Apr. 14, 2006 (JP) 2006-112194

(51) Int. Cl. H01L 21/425

(52) U.S. Cl. 438/514; 438/530

(57) ABSTRACT

An impurity is ion-implanted into the major surface of an Si substrate having a bulk microdefect density of 5×10⁶ to 5×10⁷ cm⁻³, a bulk microdefect size smaller than 100 nm, and a dissolved oxygen concentration of 1.1×10¹⁸ to 1.2×10¹⁸ cm⁻³. The Si substrate then undergoes ultra-rapid thermal annealing whose heating/cooling rate is higher than 1×10⁵° C./sec, thereby electrically activating the impurity to form at least a partial impurity diffusion layer of a semiconductor element.

### CROSS-REFERENCE TO RELATED APPLICATIONS

This application is based upon and claims the benefit of priority from prior Japanese Patent Application No. 2006-112194, filed Apr. 14, 2006, the entire contents of which are incorporated herein by reference.

### BACKGROUND OF THE INVENTION

1. Field of the Invention

The present invention relates to an annealing step of semiconductor device fabrication steps and, more particularly, to a semiconductor device fabrication method which uses an ultra-rapid thermal annealing step whose heating/cooling rate is 1×10⁵° C./sec or more, in order to form a semiconductor element having, in at least a portion, an impurity diffusion layer whose junction depth is smaller than 20 nm.

2. Description of the Related Art

The performance of a semiconductor device, particularly, an LSI can be improved by increasing the integration density, i.e., by micropatterning elements forming the LSI. As the degree of micropatterning of elements increases, however, the parasitic resistance and short-channel effect of a MOSFET increase. Therefore, the formation of a shallow low-resistance impurity diffusion layer is becoming more and more important.

A known method of forming a shallow impurity diffusion layer is to optimize ion implantation at low acceleration energy and an annealing step performed after that. On the other hand, to decrease the resistance of the impurity diffusion layer described above, annealing for activating the impurity must be performed at a high temperature.

Unfortunately, a normally used impurity such as boron (B), phosphorus (P), or arsenic (As) has a large diffusion coefficient in silicon (Si), so an RTA (Rapid Thermal Annealing) process using a halogen lamp causes in-diffusion and out-diffusion of impurity ions. This gradually makes it difficult to form shallow impurity diffusion layers.

The in-diffusion and out-diffusion described above can be suppressed by lowering the annealing temperature. If the annealing temperature is lowered, however, the activation yield of an impurity significantly decreases. This makes it difficult for the RTA process using a halogen lamp to form a low-resistance impurity diffusion layer having a shallow junction of 20 nm or less.

To solve these problems, therefore, as a method of instantaneously supplying energy necessary for impurity activation, an annealing method using a flash lamp in which a rare gas such as xenon (Xe) is sealed is being studied in recent years (e.g., Jpn. Pat. Appln. KOKAI Publication No. 2003-59854 or 2003-309079). The flash lamp can emit light with a pulse width of 100 msec or less, and the smallest pulse width is sub-msec. Annealing performed for this short time period can activate impurity ions implanted into the major surface of a wafer while the distribution of the impurity ions remains almost unchanged.

The conventional flash lamp annealing method, however, requires a large irradiation energy of 20 J/cm² or more in order to well activate an impurity. Consequently, an abrupt temperature rise occurs on the wafer surface; the wafer surface temperature instantaneously reaches 1,200° C. or more. This produces a large temperature difference between the upper and lower surfaces of the wafer, and increases the internal thermal stress of the wafer. This increase in thermal stress causes damages such as slip dislocations, fracture, and deformation of the wafer, thereby decreasing the fabrication yield.

As described above, the present flash lamp annealing method has a narrow process window, and this makes it difficult to form a shallow impurity diffusion layer without damaging the wafer.

### BRIEF SUMMARY OF THE INVENTION

According to an aspect of the present invention, there is provided a semiconductor device fabrication method comprising ion-implanting an impurity into a major surface of an Si substrate having a bulk microdefect density of 5×10⁶ to 5×10⁷ cm⁻³, a bulk microdefect size smaller than 100 nm, and a dissolved oxygen concentration of 1.1×10¹⁸ to 1.2×10¹⁸ cm⁻³, and annealing the Si substrate at a heating/cooling rate higher than 1×10⁵° C./sec, thereby electrically activating the impurity to form at least a partial impurity diffusion layer of a semiconductor element.

According to another aspect of the present invention, there is provided a semiconductor device fabrication method comprising performing annealing for fixation on an Si substrate having a bulk microdefect density of 5×10⁶ to 5×10⁷ cm⁻³, a bulk microdefect size of 10 to 100 nm, and a dissolved oxygen concentration of 1.1×10¹⁸ to 1.2×10¹⁸ cm⁻³ for a time during which an annealing temperature T and an annealing time t have a relationship indicated by t=2×10⁴ exp (−0.0124T), in order to suppress changes in bulk microdefect density and bulk microdefect size, ion-implanting an impurity into a major surface of the Si substrate, and annealing the Si substrate at a heating/cooling rate of 1×10⁵° C./sec to 1×10⁷° C./sec, thereby electrically activating the impurity to form at least a partial impurity diffusion layer of a semiconductor element.

According to still another aspect of the present invention, there is provided a semiconductor device fabrication method comprising ion-implanting an impurity into a major surface of an Si substrate having a bulk microdefect density of 5×10⁶ to 5×10⁷ cm⁻³, a bulk microdefect size of 10 to 100 nm, and a dissolved oxygen concentration of 1.1×10¹⁸ to 1.2×10¹⁸ cm⁻³ in at least a region not more than 2 mm from an outer periphery, and annealing the Si substrate at a heating/cooling rate of 1×10⁵° C./sec to 1×10⁷° C./sec, thereby electrically activating the impurity to form at least a partial impurity diffusion layer of a semiconductor element.

### BRIEF DESCRIPTION OF THE SEVERAL VIEWS OF THE DRAWING

FIG. 1 is a sectional view for explaining a semiconductor device fabrication method according to the first embodiment of the present invention by taking fabrication steps of a MOSFET as a basic element forming an LSI as an example;

FIG. 2A is a view which explains an ultra-rapid thermal annealing step, and shows an outline of the arrangement of an annealing apparatus;

FIG. 2B is a diagram which explains the ultra-rapid thermal annealing step, and shows the temperature distribution of an Si substrate;

FIG. 2C is a schematic view which explains the ultra-rapid thermal annealing step, and shows a state in which stresses are produced in an Si substrate which is being annealed;

FIG. 3 is a schematic view of a substrate section showing a state in which BMDs and dislocations are produced in Comparative Examples 1 and 5;

FIG. 4 is a schematic view of a substrate section showing a state in which BMDs and dislocations are produced in Comparative Examples 3 and 4;

FIG. 5 is a diagram showing the relationship between the BMD density and dissolved oxygen concentration with respect to wafer cracking in fabrication methods according to the first embodiment of the present invention and each comparative example;

FIG. 6 is a diagram showing the relationship between the BMD density and BMD size with respect to wafer cracking in the fabrication methods according to the first embodiment of the present invention and each comparative example;

FIG. 7 is a diagram showing the relationship of a process window to the BMD density and dissolved oxygen concentration in the semiconductor device fabrication method according to the first embodiment of the present invention;

FIG. 8 is a schematic view showing changes in BMD density and BMD size in a fabrication method of a comparative example;

FIG. 9 is a graph which explains fixation annealing, and shows the relationship between the annealing temperature and annealing time; and

FIG. 10 is a schematic view showing changes in BMD density and BMD size in a semiconductor device fabrication method according to the second embodiment of the present invention.

### DETAILED DESCRIPTION OF THE INVENTION

The process of consideration reaching the present invention will be explained first, and then semiconductor device fabrication methods according to the first and second embodiments will be explained.

Bit-like microdefects (Crystal Originated Particles: COPs) as the formation marks of voids exist on the surface of an Si substrate grown by the Czochralski: CZ) method, and have an adverse effect on the device characteristics. A known method of reducing these microdefects is to perform high-temperature annealing in a hydrogen or argon ambient. This method can form a defect-free layer from the major surface of a substrate to a device active layer having a depth exceeding 10 μm.

Also, in a wafer fabrication process of the CZ method, a large amount of oxygen elutes from a crucible made of quartz and becomes entrapped as interstitial oxygen in Si crystals. This interstitial oxygen condenses in the high-temperature annealing process described above, and forms oxygen deposits (Bulk Microdefects: BMDs) in a bulk portion having a depth of 10 μm or more. These BMDs formed inside the substrate presumably have a gettering function. Conventionally, the BMDs are formed at a high density in order to increase the device yield.

On the other hand, the present inventors inspected, by speculation and experiments, the conventionally unexamined relationship between the concentration of the interstitial oxygen, the density and size of the bulk microdefects, and the heating/cooling rate of ultra-rapid thermal annealing. Consequently, the present inventors have established a method of ensuring wafer strength by suppressing slip dislocations and brittle fracture by a fabrication method which optimizes the density and size of oxygen deposits of an Si substrate and the heating/cooling rate of annealing when forming a low-resistance impurity diffusion layer having a shallow junction.

The semiconductor device fabrication methods according to the first and second embodiments of the present invention will now be explained by taking MOSFET fabrication steps as an example.

### First Embodiment

The semiconductor device fabrication method according to the first embodiment of the present invention will be explained below by taking fabrication steps (post-extension process) of a MOSFET as a basic element forming an LSI as an example.

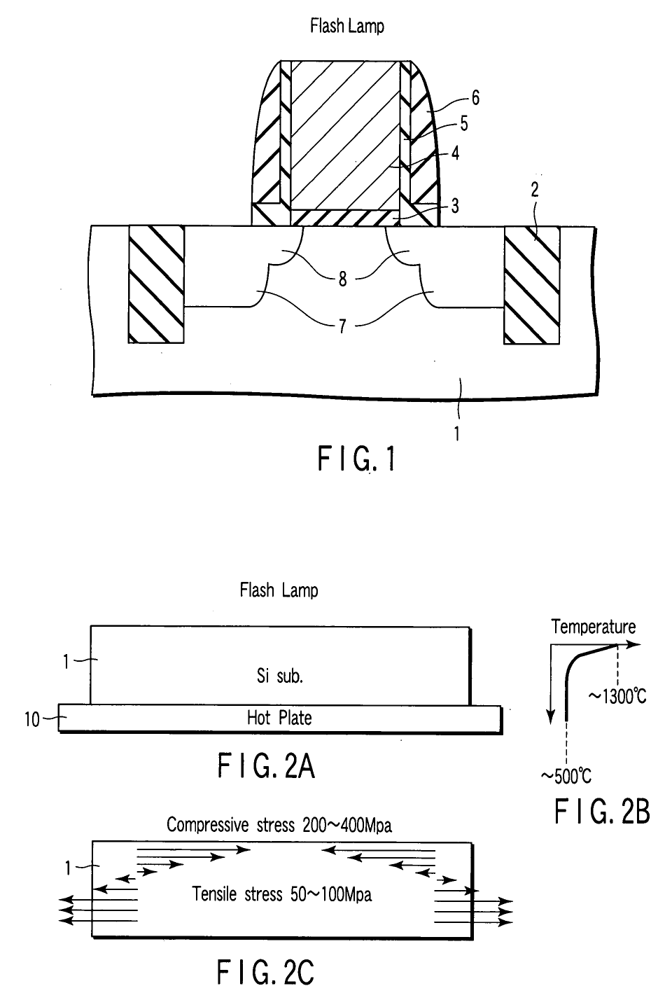

First, an Si substrate 1 having a bulk microdefect (BMD) density of 5×10⁶ to 5×10⁷ cm⁻³, a BMD size smaller than 100 nm, and a dissolved oxygen concentration (Oi) of 1.1×10¹⁸ to 1.2×10¹⁸ cm⁻³ is prepared. As shown in FIG. 1, element isolation insulating films 2 are formed in the major surface of the Si substrate 1. In this embodiment, the element isolation insulating films 2 have an STI (Shallow Trench Isolation) structure, and are buried in trenches formed in the major surface of the Si substrate 1. After that, an impurity for controlling the threshold voltage is ion-implanted into a portion corresponding to a channel region of the MOSFET, and electrically activated.

Then, a gate insulating film 3 made of SiO₂ or SiON (N concentration in surface layer <15%) is formed on the major surface of the Si substrate 1. A polysilicon (poly-Si) layer or polysilicon germanium (poly-SiGe) layer having a thickness of 50 to 150 nm is formed on the gate insulating film 3 by LP-CVD. The Ge concentration in the polysilicon germanium layer is 10% to 30%. P or As is ion-implanted into the polysilicon layer or polysilicon germanium layer when forming an n-channel MOSFET, and B is ion-implanted into the layer when forming a p-channel MOSFET, at a concentration of 3×10¹⁵ to 8×10¹⁵ cm⁻². The obtained layer is patterned into the shape of a gate electrode 4 by using photolithography and reactive ion etching.

Subsequently, an SiO₂ film and Si₃N₄ film are formed on the entire surface and selectively left behind on the side surfaces of the gate electrode 4 by etch back using reactive ion etching. This step forms sidewall spacers 5 and 6 made of SiO₂ and Si₃N₄. The sidewall spacers 5 and 6 prevent a silicide reaction in a subsequent step.

After that, the method of post-extension process is used to ion-implant a desired amount of a desired impurity into source/drain regions 7 and their extended portions (extension regions) 8. In this step, the ions are implanted into the gate electrode 4 as well. Finally, the gate electrode 4 contains the impurity P or impurities As and B of the principal conductivity type at a concentration of about 5×10¹⁵ to 1×10¹⁶ cm⁻².

Then, a flash lamp or laser is used to perform ultra-rapid thermal annealing whose heating/cooling rate is higher than 1×10⁵° C./sec, thereby electrically activating the impurity doped into the source/drain regions 7, extension regions 8, and gate electrode 4. In this ultra-rapid thermal annealing step, as shown in FIG. 2A, while the Si substrate (Si sub.) is heated on a hot plate 10, annealing is performed by irradiating the major surface of the Si substrate 1 with pulsed light from the flash lamp, thereby activating the implanted impurity ions. When the hot plate 10 heats the lower surface of the Si substrate 1 to about 500° C., for example, the major surface of the Si substrate 1 is heated to about 1,300° C., resulting in a temperature distribution as shown in FIG. 2B.

Consequently, as shown in FIG. 2C, a compressive stress of 200 to 400 MPa is applied on the major surface of the Si substrate 1, and a tensile stress of 50 to 100 MPa is applied on the lower surface.

Note that in the above explanation, the impurity doped into the source/drain regions 7, extension regions 8, and gate electrode 4 is electrically activated by ultra-rapid thermal annealing. However, it is also possible to perform annealing at a low temperature for a relatively long time by using the existing RTA apparatus before the formation of the extension regions 8, thereby diffusing and activating the implanted impurity in the source/drain regions 7 and gate electrode 4. After that, the impurity is ion-implanted into the extension regions 8, and the implanted impurity in the extension regions 8 is diffused and activated by performing ultra-rapid thermal annealing under the above-mentioned conditions. In this fabrication method, the RTA process removes defects produced by the ion implantation of the impurity into the source/drain regions 7. This reduces the variations in fabrication and stabilizes the characteristics of the MOSFET.

Although fabrication steps after that are not shown, an Ni film, a Co film, a Pt film, a Pd film, or a metal film mainly containing an alloy of these metals is vapor-deposited to have a thickness of 10 nm or less in a salicide step, thereby selectively forming NiSi, NiSi₂, CoSi, CoSi₂, PtSi, or Pd₂Si in the exposed portions of Si or SiGe. Subsequently, unreacted Ni is removed by hydrolysis by addition of sulfuric acid, a silicon oxide film serving as an interlayer dielectric film is deposited, and contact holes are formed in those portions of the silicon oxide film which correspond to the source/drain regions 7 and gate electrode 4. Then, a metal layer or the like is formed on the silicon oxide film and in the contact holes and patterned to form interconnections connecting to the gate electrode 4 and source/drain regions 7 through the contact holes.

A semiconductor device in which the MOSFET having the shallow extension regions (impurity diffusion layers) 8 of 20 nm or less is formed is completed by the fabrication steps as described above.

The semiconductor device (MOSFET) formed by the fabrication method of the first embodiment and Comparative Examples 1 to 5 in which similar semiconductor devices were formed by using Si substrates different in bulk microdefect density, bulk microdefect size, and dissolved oxygen concentration will be explained below.

### COMPARATIVE EXAMPLE 1

A MOSFET was formed on an Si substrate having a bulk microdefect [BMD] density of 7×10⁷ cm⁻³ or more, a BMD size of 100 nm or less, and a dissolved oxygen concentration [Oi] of 1.3×10¹⁸ cm⁻³ or more.

### COMPARATIVE EXAMPLE 2

A MOSFET was formed on an Si substrate having a bulk microdefect [BMD] density of 3×10⁷ cm⁻³ or more, a BMD size of 100 nm or less, and a dissolved oxygen concentration [Oi] of 1.1×10¹⁸ cm⁻³ or less.

### COMPARATIVE EXAMPLE 3

A MOSFET was formed on an Si substrate having a bulk microdefect [BMD] density of 1×10⁶ to 1×10⁷ cm⁻³, a BMD size of 100 nm or less, and a dissolved oxygen concentration [Oi] of 1.3×10¹⁸ cm⁻³ or more.

### COMPARATIVE EXAMPLE 4

A MOSFET was formed on an Si substrate having a bulk microdefect [BMD] density of 1×10⁷ cm⁻³ or less, a BMD size of 100 nm or less, and a dissolved oxygen concentration [Oi] of 1.1×10¹⁸ cm⁻³ or less.

### COMPARATIVE EXAMPLE 5

A MOSFET was formed on an Si substrate having a bulk microdefect [BMD] density of 1×10⁷ cm⁻³ or more, a BMD size of 100 nm or more, and a dissolved oxygen concentration [Oi] of 1.1×10¹⁸ cm⁻³ or more.

(Evaluation)

When the MOSFETs were formed on the Si substrates of the first embodiment and Comparative Examples 1 to 5, deformation or slip dislocations were found in the Si substrates of Comparative Examples 1 to 5 in the ultra-rapid thermal annealing step (in this embodiment, the flash lamp annealing step), and this increased the probability of breakage. In the first embodiment, however, none of deformation, slip dislocations, and wafer cracking occurred in the Si substrate, so it was possible to form a micropatterned MOSFET having high driving power.

The following findings were obtained by analyzing the semiconductor device fabrication method according to the first embodiment and the Si substrates of the comparative examples after the flash lamp annealing step.

When the Si substrate which was processable without any cracking at a BMD density of 1×10⁸ cm⁻³ or more was evaluated by an X-ray topograph, fine white brilliant points were observed at a high density, indicating the occurrence of X-ray scattering. When the brilliant points were observed with a sectional TEM, a large number of dislocation-like defects were observed in the <111> direction, and these defects reached a depth of 100 μm or more from the surface. In addition, the deformation amount of the Si substrate increased as the BMD density and BMD size increased.

The differences between the obtained results will be theoretically considered below by comparing the first embodiment with the comparative examples.

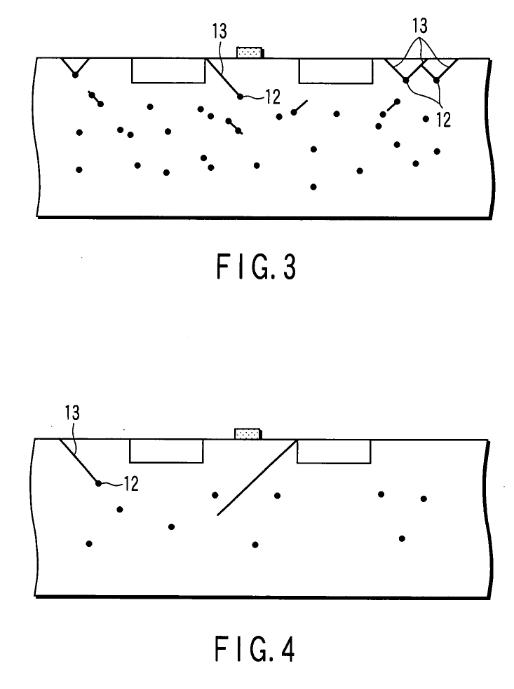

In the Si substrate (FIG. 3) having a high BMD density or large BMD size as in [Comparative Example 1] or [Comparative Example 5], dislocations 13 occurred from BMDs 12 as start points presumably because the thermal stress caused by the flash lamp concentrated to the BMDs as discontinuous points in the crystal. Wafer cracking occurred probably because the substrate strength decreased owing to the high-density dislocations. The deformation amount increased without wafer cracking perhaps because the dislocations 13 starting from the BMDs 12 functioned as slips to relax the thermal stress and caused plastic deformation.

In the Si substrate (FIG. 4) having a low BMD density of 1×10⁷ cm⁻³ or less as in [Comparative Example 3] or [Comparative Example 4], the density of white brilliant points observed by an X-ray topograph was low, but the wafer cracked even under the conditions. This is probably because a small number of BMDs were unable to function as slips to relax the thermal stress by the flash lamp, so the thermal stress built up and reached fracture. In addition, the BMDs 12 can also function as end points of the dislocations 13 as well as their start points and have an effect of stopping the advance of dislocations from other portions. If the BMD density is low, therefore, cracking may occur since BMDs cannot stop the advance of dislocations.

Generally, when the dissolved oxygen concentration in an Si substrate increases, oxygen diffuses or adheres and effectively stops the advance or movement of slip dislocations.

This presumably has influence on wafer cracking in the Si substrate having a low dissolved oxygen concentration [Oi] of 1.1×10¹⁸ cm⁻³ or less as in [Comparative Example 2] or [Comparative Example 4].

However, wafer cracking was serious in the Si substrate having a high dissolved oxygen concentration [Oi] of 1.3×10¹⁸ cm⁻³ or more as in [Comparative Example 1] or [Comparative Example 3] as well. This is so perhaps because in the heating step, before the ultra-rapid thermal annealing step using the flash lamp, of the semiconductor device fabrication steps, oxygen condensed and deposited inside the substrate to increase the BMD density or accelerate the growth of BMDs, thereby adversely affecting wafer cracking.

The above results indicate that when performing ultra-rapid thermal annealing whose heating/cooling rate is higher than 1×10⁵° C./sec, the BMD density and dissolved oxygen concentration inside the Si substrate have influence on wafer cracking if they are too low or too high, so it is probably favorable to maintain each value at a value controlled within a certain range. It is also favorable to maintain the BMD density and BMD size at values controlled within certain ranges.

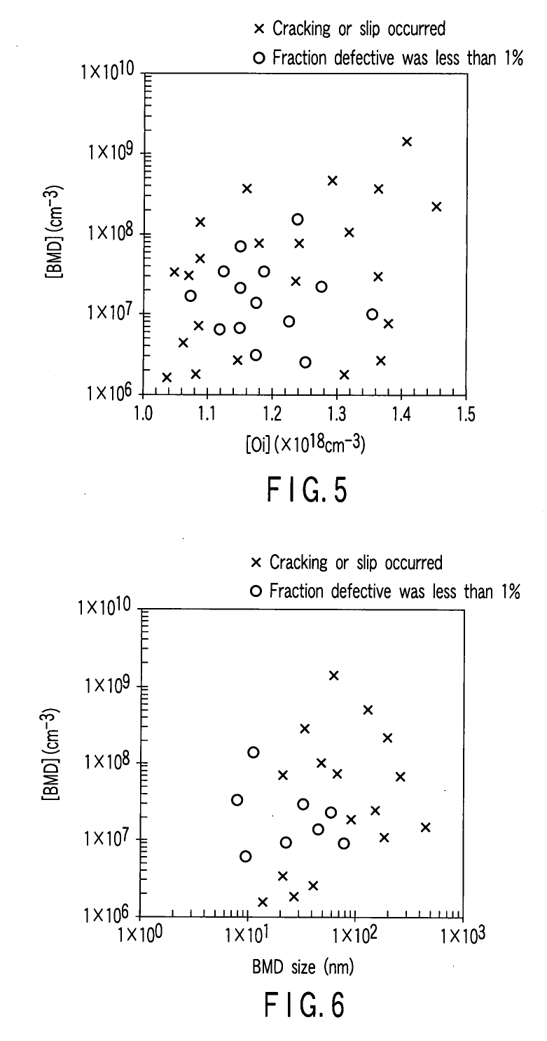

FIG. 5 collectively shows the relationships between the BMD density and dissolved oxygen concentration inside the Si substrate of this embodiment and the comparative examples described above. Symbol ◯ indicates that the fraction defective was less than 1% after the experiment, and symbol X indicates that cracking or slip occurred.

FIG. 6 collectively shows the relationships between the BMD density and BMD size of this embodiment and the comparative examples described above. Similar to FIG. 5, symbol ◯ indicates that the fraction defective was less than 1% after the experiment, and symbol X indicates that cracking or slip occurred.

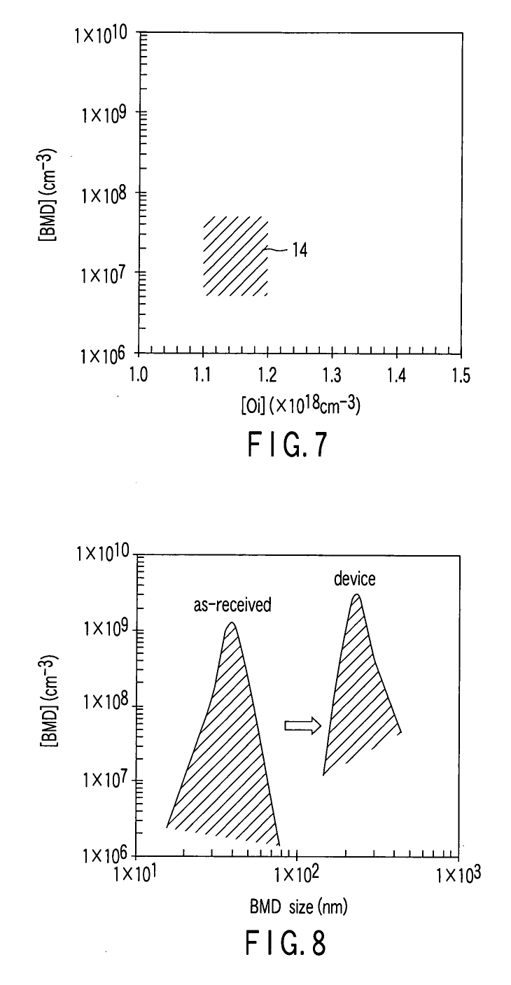

The results of the experiments demonstrate that a hatched region 14 shown in FIG. 7 indicates favorable application ranges of the bulk microdefect [BMD] density and dissolved oxygen concentration [Oi], i.e., 5×10⁶ cm⁻³<[BMD]<5×10⁷ cm⁻³ and 1.1×10¹⁸ cm⁻³<[Oi]<1.2×10¹⁸ cm⁻³. If the BMD density is 5×10⁶ cm⁻³ or more, BMDs act as slip dislocation sources but inhibit the advance of slip dislocations at the same time. If the BMD density is 5×10⁷ cm⁻³ or more, however, the effect of inhibiting the advance of slip dislocations weakens, and BMDs more strongly act as slip dislocation sources.

On the other hand, the dissolved oxygen concentration is preferably high because dissolved oxygen has a function of increasing the crystal strength and adhering slip dislocations. If the dissolved oxygen concentration is too high, however, dissolved oxygen often condenses and deposits (to form BMD seeds) in a high-temperature annealing process during the course of LSI fabrication. Accordingly, a favorable application range of the dissolved oxygen concentration [Oi] is probably 1.1×10¹⁸ cm⁻³<[Oi]<1.2×10¹⁸ cm⁻³.

The range of the heating/cooling rate [T1] of ultra-rapid thermal annealing described above is preferably 1×10⁵° C.<[α]<1×10⁷° C. for the following reasons. That is, if this heating/cooling rate is 1×10⁵° C. or less, impurity diffusion increases to become no longer negligible. If the heating/cooling rate is 1×10⁷° C. or more, the load on the annealing apparatus increases to make ultra-rapid thermal annealing difficult to perform.

Furthermore, the range of the temperature [T2] of the major surface of the Si substrate 1 resulting from ultra-rapid thermal annealing is preferably 1,000° C.<[T2]<1,400° C. If this temperature is 1,000° C. or less, no desired high-concentration activation can be expected. If the temperature is 1,400° C. or more, the Si substrate 1 melts.

The BMD size [SZ] preferably falls within the range of 10 nm<[SZ]<100 nm. If the BMD size is 10 nm or less, BMDs do not act as slip dislocation sources. When the BMD size is larger than 10 nm, BMDs act as slip dislocation sources and achieve the capability of inhibiting the advance of slip dislocations and the gettering effect. If the BMD size is 100 nm or more, however, BMDs act as slip dislocation sources but cannot inhibit the movement of slip dislocations any longer.

### Second Embodiment

A semiconductor device fabrication method according to the second embodiment of the present invention will be explained below. The second embodiment differs from the first embodiment in that a semiconductor element (MOSFET) is fabricated after a pre-processing step (fixation annealing) for maintaining a state in which the BMD density of an Si substrate 1 is 5×10⁶ to 5×10⁷ cm⁻³ and the BMD size of the substrate is smaller than 100 nm is performed in a step before flash lamp annealing.

As explained in the first embodiment described above, even when an Si substrate in which the BMD density is controlled within a certain range is used, BMDs may change in the heating step performed before flash lamp annealing during the process of fabricating a semiconductor device. Generally, interstitial oxygen dissolved in the Si substrate 1 condenses and deposits through a high-temperature, long-time heating step. That is, the heating step accelerates the nucleation and growth of BMDs and increases the density and size of the BMDs as shown in FIG. 8. Both the BMD density and size (device) of an Si substrate having undergone MOSFET fabrication steps increase from the BMD density and size (as-received) of the Si substrate in the initial state.

In the semiconductor device fabrication method according to the second embodiment, therefore, fixation annealing is performed at a temperature of 600° C. to 800° C. for 3 hrs or less in order to suppress changes in BMD density and BMD size particularly in a step before flash lamp annealing. An annealing temperature of about 600° C. is necessary to fabricate a high-quality LSI (having high driving power and high reliability). An annealing temperature of 800° C. or less is too low to cause the growth of BMD nuclei. If the annealing temperature is 800° C. or more, both the BMD density and size increase.

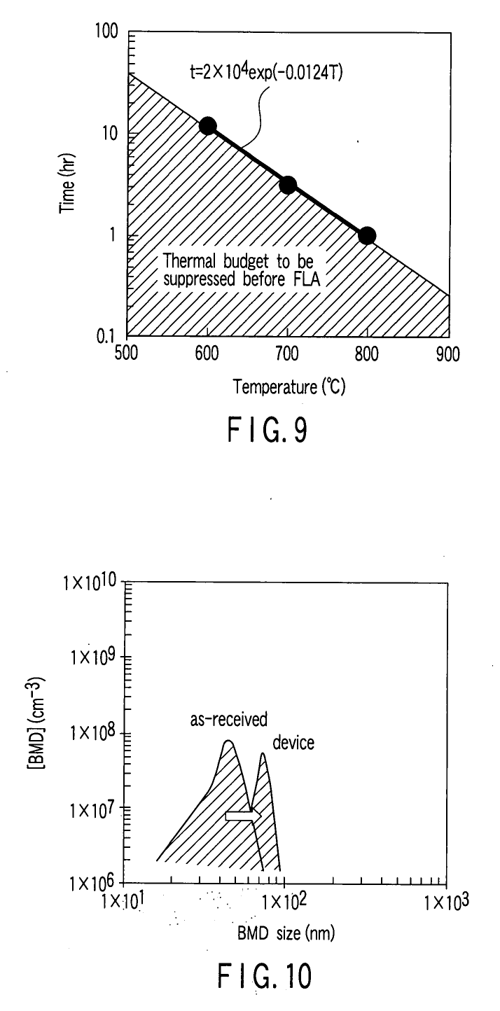

As shown in FIG. 9, this fixation annealing is desirably performed in a region (hatched region 15) in which the relationship between an annealing temperature T (° C.) and annealing time t (hr) is lower than a line represented by t=2×10⁴ exp (−0.0124T).

In semiconductor device fabrication steps, various annealing steps are performed to, e.g., densify STI and activate an impurity in addition to CVD steps for forming a gate insulating film, gate polysilicon, gate sidewall spacers, and the like. Conventionally, a thermal budget irrelevant to BMD suppression is assumed. However, the second embodiment performs a thermal budget in a nitrogen gas ambient at a temperature of 600° C. to 800° C. for 3 hrs or less. This suppresses the formation and growth of BMDs, and makes it possible to fabricate a semiconductor device without any technical difficulty (e.g., a wafer annealing step can be changed from furnace batch processing to single wafer processing).

By setting the process conditions as described above, as shown in FIG. 10, the changes in BMD density and BMD size can be decreased and controlled within application ranges without departing from the BMD conditions. Accordingly, slip dislocations, deformation, fracture, and the like of the wafer can be avoided in the flash lamp annealing step. Consequently, it is possible to stably and readily fabricate a high-performance micropatterned MOSFET having an impurity diffusion layer (extension region) with a small junction depth of 20 nm or less.

Note that the first and second embodiments described above have explained the annealing apparatus using the xenon flash lamp as a light source for emitting light. However, the present invention is not limited to these embodiments. For example, the present invention is also applicable to flash lamps using another rare gas, mercury, and hydrogen, and light sources such as an arc discharge lamp, excimer laser, Ar laser, N₂ laser, YAG laser, titanium sapphire laser, CO laser, and CO₂ laser.

Also, the present invention has been explained by taking the MOSFET fabrication method as an example. However, the present invention is similarly applicable to all semiconductor elements having, in at least a portion, a low-resistance impurity diffusion layer with a shallow junction of 20 nm or less.

Furthermore, when an Si substrate is annealed at a heating/cooling rate of 1×10⁵° C./sec to 1×10⁷° C./sec in the LSI fabrication process, slip dislocations or crack-like marks easily form in a region 2 mm from the outer periphery of the Si substrate (see the temperature distribution shown in FIG. 2B). In a post-processing step after that, the wafer breaks from these slip dislocations or marks as start points. That is, wafer breakage often advances from the outer periphery to the inner periphery. Therefore, it is also possible to control BMDs not on the entire surface of an Si substrate but in an outer peripheral portion acting as a trigger of breakage, particularly, in a region 2 mm or less from the outer periphery.

As described above, one aspect of the present invention can ensure wafer strength against slip dislocations and brittle fracture caused by ultra-rapid thermal annealing. This makes it possible to widen the process window and stabilize the process. Also, a shallow low-resistance diffusion layer can be formed without any damage. Since this facilitates micropatterning, a high-performance MOSFET can be fabricated. This increases the fabrication yield and stabilizes the operation of fabrication steps.

Additional advantages and modifications will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

What is claimed is:

1. A semiconductor device fabrication method comprising:
ion-implanting an impurity into a major surface of an Si substrate having a bulk microdefect density of 5×10⁶ to 5×10⁷ cm⁻³, a bulk microdefect size smaller than 100 nm, and a dissolved oxygen concentration of 1.1×10¹⁸ to 1.2×10¹⁸ cm⁻³; and
annealing the Si substrate at a heating/cooling rate higher than 1×10⁵° C./sec, thereby electrically activating the impurity to form at least a partial impurity diffusion layer of a semiconductor element.

2. A method according to claim 1, further comprising performing annealing for fixation which suppresses changes in bulk microdefect density and bulk microdefect size, before the annealing whose heating/cooling rate is higher than 1×10⁵° C./sec.

3. A method according to claim 2, wherein performing the annealing for fixation is a thermal budget performed at a temperature of 600° C. to 800° C. for a time shorter than 3 hrs.

4. A method according to claim 1, wherein the heating/cooling rate of the ultra-rapid thermal annealing is lower than 1×10⁷° C./sec.

5. A method according to claim 1, wherein a temperature range of the major surface of the Si substrate resulting from the ultra-rapid thermal annealing is 1,000° C. to 1,400° C.

6. A method according to claim 1, wherein the bulk microdefect size is larger than 10 nm.

7. A method according to claim 1, wherein a junction depth of the impurity diffusion layer is smaller than 20 nm.

8. A semiconductor device fabrication method comprising:
performing annealing for fixation on an Si substrate having a bulk microdefect density of 5×10⁶ to 5×10⁷ cm⁻³, a bulk microdefect size of 10 to 100 nm, and a dissolved oxygen concentration of 1.1×10¹⁸ to 1.2×10¹⁸ cm⁻³ for a time during which an annealing temperature T and an annealing time t have a relationship indicated by t=2×10⁴ exp (−0.0124T), in order to suppress changes in bulk microdefect density and bulk microdefect size;
ion-implanting an impurity into a major surface of the Si substrate; and
annealing the Si substrate at a heating/cooling rate of 1×10⁵° C./sec to 1×10⁷° C./sec, thereby electrically activating the impurity to form at least a partial impurity diffusion layer of a semiconductor element.

9. A method according to claim 8, further comprising performing annealing for fixation which suppresses changes in bulk microdefect density and bulk microdefect size, before the annealing whose heating/cooling rate is 1×10⁵° C./sec to 1×10⁷° C./sec.

10. A method according to claim 9, wherein performing the annealing for fixation is a thermal budget performed at a temperature of 600° C. to 800° C. for a time shorter than 3 hrs.

11. A method according to claim 9, wherein a temperature range of the major surface of the Si substrate resulting from the ultra-rapid thermal annealing is 1,000° C. to 1,400° C.

12. A method according to claim 9, wherein a junction depth of the impurity diffusion layer is smaller than 20 nm.

13. A semiconductor device fabrication method comprising:
ion-implanting an impurity into a major surface of an Si substrate having a bulk microdefect density of 5×10⁶ to 5×10⁷ cm⁻³, a bulk microdefect size of 10 to 100 nm, and a dissolved oxygen concentration of 1.1×10¹⁸ to 1.2×10¹⁸ cm⁻³ in at least a region not more than 2 mm from an outer periphery; and
annealing the Si substrate at a heating/cooling rate of 1×10⁵° C./sec to 1×10⁷° C./sec, thereby electrically activating the impurity to form at least a partial impurity diffusion layer of a semiconductor element.

14. A method according to claim 13, further comprising performing annealing for fixation which suppresses changes in bulk microdefect density and bulk microdefect size, before the annealing whose heating/cooling rate is 1×10⁵° C./sec to 1×10⁷° C./sec.

15. A method according to claim 14, wherein performing the annealing for fixation is a thermal budget performed at a temperature of 600° C. to 800° C. for a time shorter than 3 hrs.

16. A method according to claim 13, wherein a temperature range of the major surface of the Si substrate resulting from the ultra-rapid thermal annealing is 1,000° C. to 1,400° C.

17. A method according to claim 13, wherein a junction depth of the impurity diffusion layer is smaller than 20 nm.
